(19) United States
(12) Patent Application Publication
(10) Pub. No.: US 2026/0353579 A1
(43) Pub. Date: Nov. 5, 2026

(54) ORTHOGONAL POSITIONING OF HIGH-SPEED INTERCONNECTIONS

(71) Applicant: Cisco Technology, Inc., San Jose, CA (US)

(72) Inventors: Amendra Koul, San Francisco, CA (US); David Nozadze, San Jose, CA (US); Sayed Ashraf Mamun, San Jose, CA (US); Mike Sapozhnikov, San Jose, CA (US); D. Brice Achkir, Livermore, CA (US)

(21) Appl. No.: 19/194,800

(22) Filed: Apr. 30, 2025

(51) Int. Cl. H05K 5/02; H05K 5/00; H05K 7/20

(52) U.S. Cl. CPC H05K 5/0247; H05K 5/0026; H05K 7/20136

(57) ABSTRACT

An electronic device including a chassis, a first printed circuit board (PCB) mounted in a substantially horizontal plane in the chassis, the first PCB including a processor for the electronic device, a second PCB mounted in the chassis substantially orthogonally to the first PCB, the second PCB including first (e.g., female) electrical connector components that are open to a front-side of the electronic device and are respectively configured to receive corresponding second (e.g., male) electrical connector components, and connection cables, connecting the first electrical connector components to the first PCB, the connection cables configured to supply input/output data signals from, and to, the processor on the first PCB.

### TECHNICAL FIELD

The present disclosure relates to a hardware configuration for a network device that hosts high-speed input/output (I/O) electrical connector components.

### BACKGROUND

Switches and routers are housed in enclosures that typically include a plurality of ports in communication with optical and/or electrical cables via front panel electrical connectors. Notably, as the speed or bit rate of electrical communication via these electrical connectors increases, more heat is generated by the connectors themselves and supporting electrical components housed inside the enclosure. To reduce undesirable heat buildup inside the enclosure, back-side fans on the enclosure are configured to draw cool air through front-side vents or holes, adjacent the front panel electrical connectors, and pass that cool air over heatsink cooling fins mounted toward the rear of the enclosure. As the number of connectors increases on the front side of the enclosures, however, less space is available for front-side vents or holes, thus limiting the amount of colling air that can be drawn into the enclosures.

### BRIEF DESCRIPTION OF THE DRAWINGS

FIG. 1 shows a perspective view of several hardware components of a network device, including a chassis base, main processor printed circuit board (PCB), and Application Specific Integrated Circuit (ASIC), according to an example embodiment.

FIG. 2 shows a perspective view of additional hardware components of the network device, including an orthogonally-oriented PCB, according to an example embodiment.

FIG. 3 shows a perspective view of still more hardware components of the network device including a heatsink and power supplies, according to an example embodiment.

FIG. 4 shows a perspective view of an internally-facing side of the orthogonally-oriented PCB, according to an example embodiment.

FIG. 5 shows high-speed electrical connectors mounted to, and air flow passages defined in, the orthogonally-oriented PCB, according to an example embodiment.

FIG. 6 shows a perspective view of a plurality of electrical connector cages attached to the high-speed electrical connectors, according to an example embodiment.

FIG. 7 shows a perspective view of the network device including a front panel cover with ventilation holes and openings for the electrical connector cages, according to an example embodiment.

FIG. 8 is a perspective view of the network device including a chassis case, according to an example embodiment.

FIG. 9 is a flowchart depicting a series of operations to assemble a network device, according to an example embodiment.

FIG. 10 is a block diagram of a computing device that may be configured consistent with the described network device, according to an example embodiment.

### DETAILED DESCRIPTION

### Overview

An electronic device, such as a network switch or router, includes a chassis, a first printed circuit board (PCB) mounted in a substantially horizontal plane in the chassis, the first PCB including a processor for the electronic device, a second PCB mounted in the chassis substantially orthogonally to the first PCB, the second PCB including first (e.g., female) electrical connector components that are open to a front-side of the electronic device and are respectively configured to receive corresponding second (e.g., male) electrical connector components, and connection cables, connecting the first electrical connector components to the first PCB, the connection cables configured to supply input/output data signals from, and to, the processor on the first PCB.

In another embodiment, an electronic device, such as a network switch or router, includes a chassis, a first printed circuit board (PCB) mounted in a substantially horizontal plane in the chassis, the first PCB including a processor for the electronic device, a second PCB mounted in the chassis substantially orthogonally to the first PCB, the second PCB including input/output data connectors, connector cages respectively attached to the input/output data connectors and open to a front-side of the electronic device, the connector cages configured to receive corresponding male electrical connectors, a front panel cover including openings configured to support ends of the connector cages, and connection cables, connecting the input/output data connectors to the first PCB, and configured to supply input/output data signals from, and to, the processor on the first PCB.

In another embodiment, a method for assembling a network device includes mounting a first printed circuit board (PCB) in a substantially horizontal plane in a chassis, the first PCB including a processor for the electronic device, mounting a second PCB in the chassis substantially orthogonally to the first PCB, the second PCB including input/output data connectors, attaching connector cages to the input/output data connectors, the input/output data connectors being open to a front-side of the electronic device and configured to receive corresponding male electrical connectors, fastening a front panel cover to the chassis, the front panel cover including openings that are configured to support ends of the connector cages, and attaching connection cables between the input/output data connectors and the first PCB, the connection cables being configured to supply input/output data signals from, and to, the processor on the first PCB.

### Example Embodiments

Presented herein are arrangements for an orthogonal connection expansion for high speed interconnections that can allow for more complex devices, such as those that use a 1024-point Radix type solution, with an improved signal integrity and thermal performance.

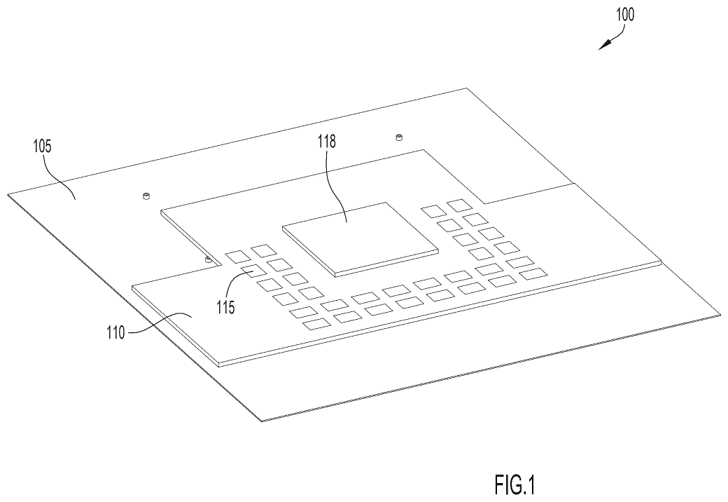

FIGS. 1-8 show a sequence of assembly views of a network device 100, such as a switch or router, as different/additional components are added to the overall assembly. FIG. 1 shows a perspective view of several hardware components of an electronic device such as network device 100, including a chassis base 105, main processor printed circuit board (PCB) 110 mounted to the chassis base 105, and an Application Specific Integrated Circuit (ASIC) 118 mounted and electrically connected to the main processor PCB 110, according to an example embodiment. Main processor PCB 110 includes a plurality of base pads 115 that are in communication with ASIC 118 via PCB traces (not shown).

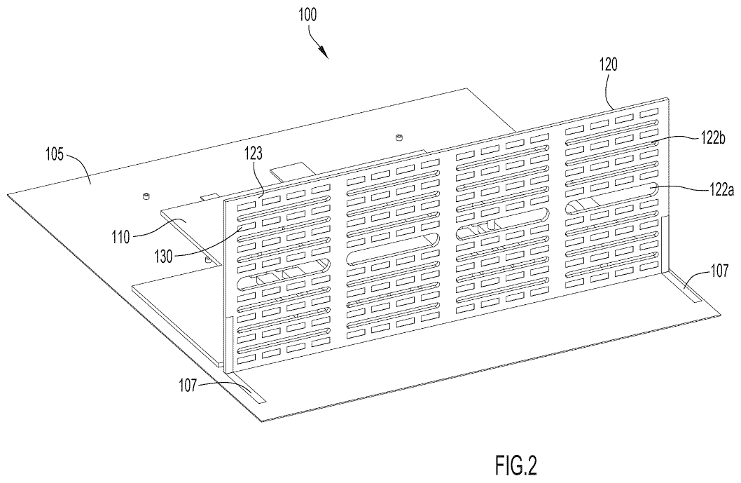

FIG. 2 shows a perspective view of additional hardware components of the network device 100 including an orthogonally-oriented PCB 120, according to an example embodiment. More specifically, orthogonally-oriented PCB 120 includes large air flow passages 122a (having a first relatively large area) and small air flow passages 122b (having a second relatively small area, i.e., smaller than the first area). High-speed electrical connector mounting pads 130 for, e.g., input/output data, are mounted on a front-side 123 of orthogonally-oriented PCB 120. As shown, orthogonally-oriented PCB 120 is configured to be in a plane substantially orthogonal or perpendicular to a plane of chassis base 105 so that, as is depicted in subsequent figures, electrical connector receptacles (e.g., cages) are open to a front side of the network device 100 when mounted on the orthogonally-oriented PCB 120. Orthogonally-oriented PCB 120 may be secured in place with, e.g., metal brackets 107, or other mounting techniques or hardware, such as slots, rails, etc.

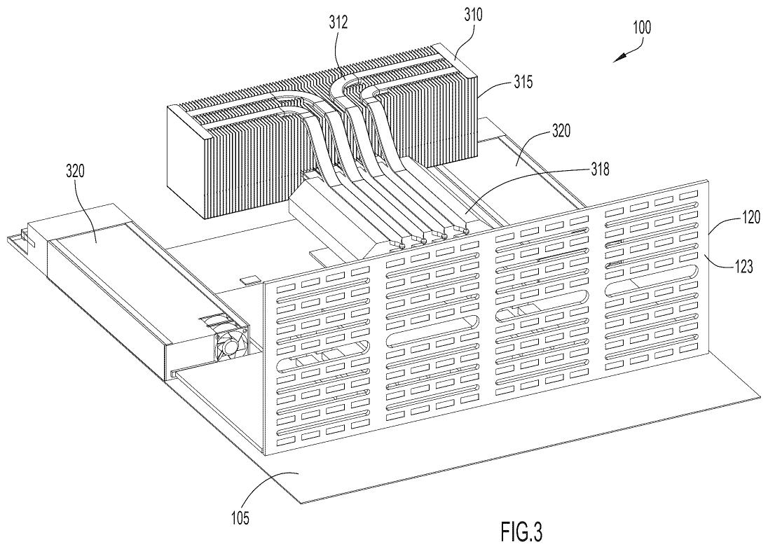

FIG. 3 shows a perspective view of still more hardware components of the network device including a heatsink 310 that includes cooling channels 312 and cooling fins 315. Heatsink 310 includes a hood or cover 318 that covers ASIC 118, which is partially hidden behind orthogonally-oriented PCB 120 in this view. Power supplies 320 are mounted on either side of the heatsink 310 toward a rear of the chassis base 105.

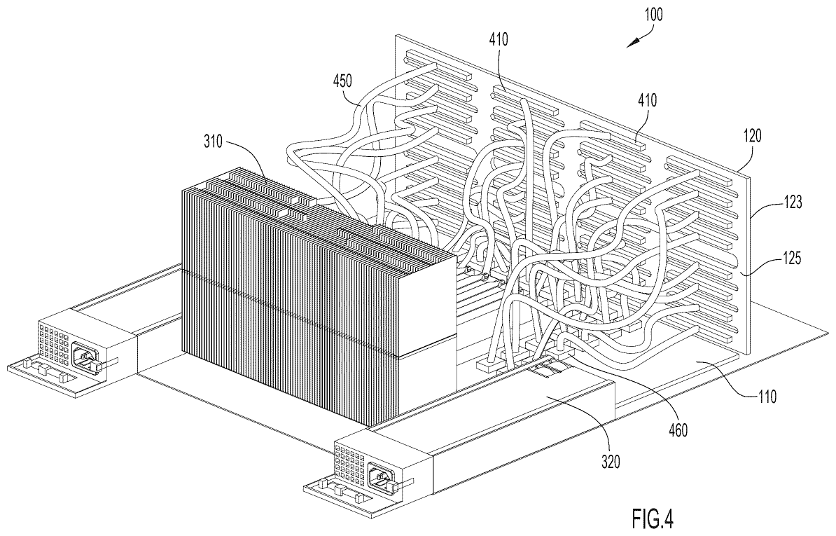

FIG. 4 shows a perspective view of an internally-facing side 125 of the orthogonally-oriented PCB 120, according to an example embodiment. In this view, back-side electrical connectors 410 are configured to aggregate, e.g., four high-speed electrical connector mounting pads 130 on the front-side 123 of orthogonally-oriented PCB 120. Respective connection cables 450 electrically connect individual signal wires (not shown) from back-side electrical connectors 410 to main processor PCB 110 via PCB connectors 460 that are mounted to connector base pads 115 directly, or via an associated connector receptacle mounted to connector base pads 115.

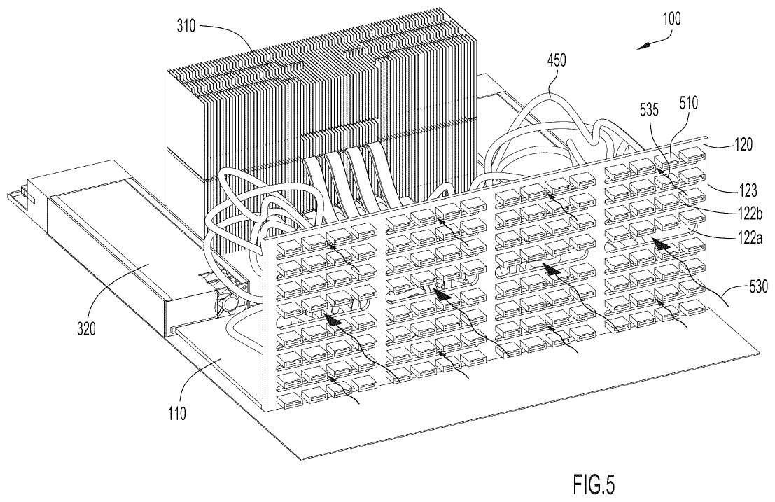

FIG. 5 shows high-speed I/O connectors 510 (or input/output data connectors) mounted to front-side 123 of orthogonally-oriented PCB 120. In the context of the present embodiments, “high-speed” means, e.g., 25 Gbps or higher. As show in this example, four high-speed I/O connectors 510 are arranged or grouped together, matching a corresponding number of high-speed electrical connector mounting pads 130 (FIG. 2). High-speed electrical connector mounting pads 130 are in electrical communication, via orthogonally-oriented PCB 120, with respective back-side electrical connectors 410 as depicted in FIG. 4. FIG. 5 also shows large air flow passages 122a and small air flow passages 122b that extend horizontally under each set of four high-speed I/O connectors 510. Large arrows 530 and small arrows 535 represent relative volumes of air that can be drawn through large air flow passages 122a and small air flow passages 122b, respectively.

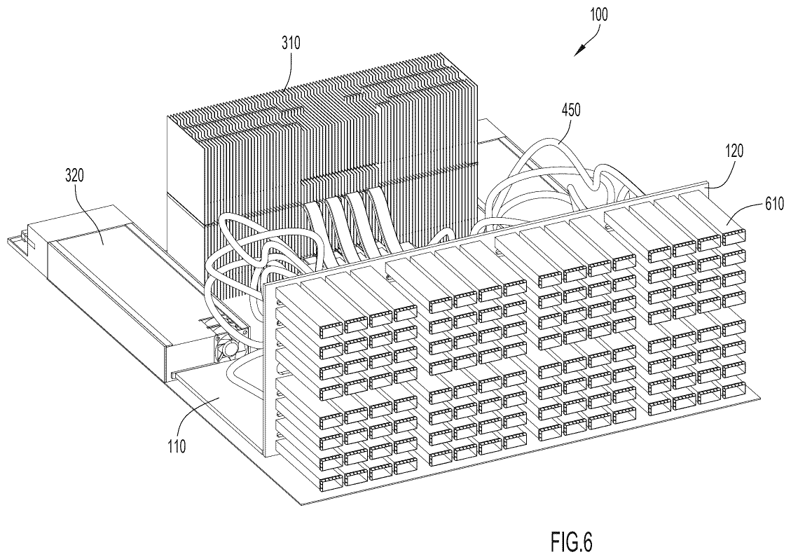

FIG. 6 shows a perspective view of a plurality of connector cages 610 that are mounted or attached to the high-speed I/O connectors 510, according to an example embodiment. In one implementation, connector cages 610 and high-speed I/O connectors 510 are parts of female (or first) components of a Quad Small Form-factor Pluggable (QSFP), QSFP Double Density (QSFP-DD), or OSFP (Octal Small Form-Factor Pluggable) type connector. Those skilled in the art will appreciate that connectors with other form factors may also be employed in the network device 100 described and depicted herein.

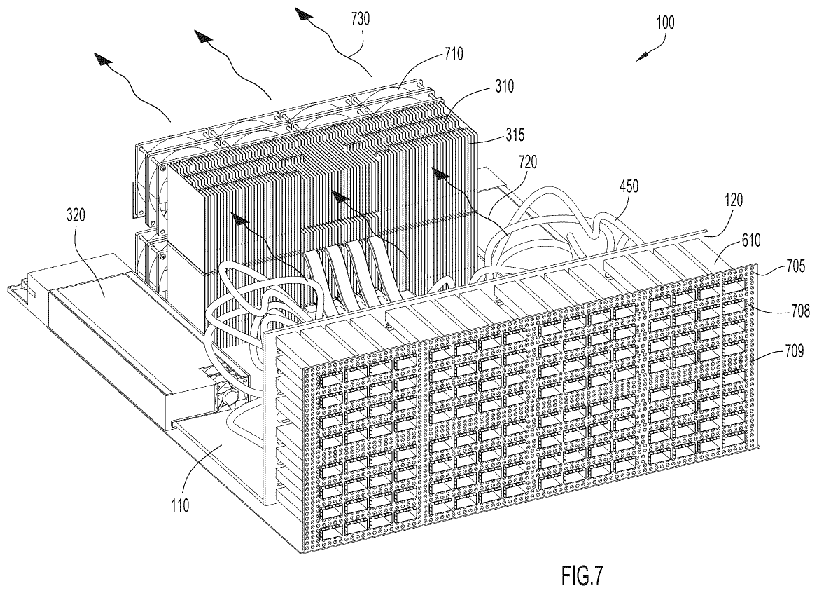

FIG. 7 is a perspective view of the network device 100 including a front panel cover 705 with openings 708 corresponding to connector cages 610, according to an example embodiment. Front panel cover 705 includes a plurality of holes or perforations 709 that allow cool outside air, depicted by arrows 720, to be drawn in by fans 710 to remove heat, as indicated by arrows 730, by passing cooler outside air over cooling fins 315 of heatsink 310. Openings 708 provide structural support for the open ends of connector cages 610.

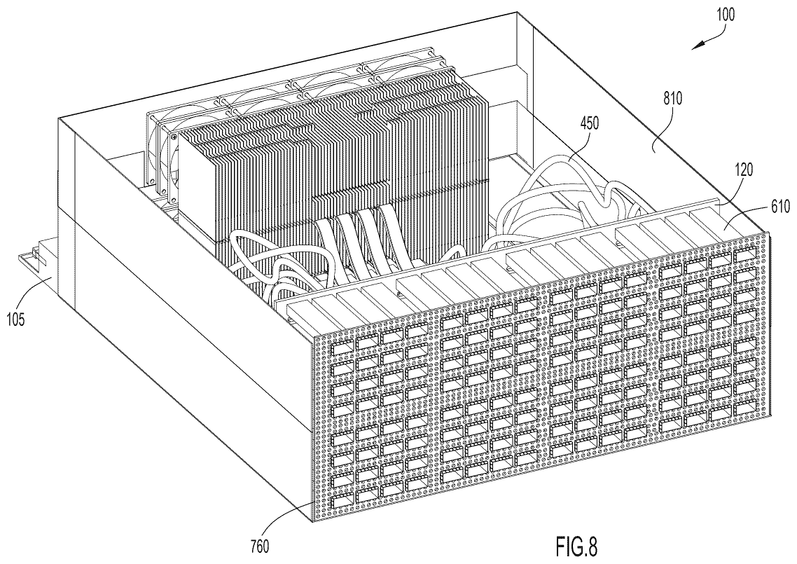

FIG. 8 is a perspective view of the network device 100 including a chassis case 810 that is mounted on chassis base 105, according to an example embodiment. Chassis case 810 abuts side edges 760 of front panel cover 705. Network device 100 may also include a top cover (not shown). Once assembled, network device 100 is fully enclosed and shielded from electromagnetic interference (EMI) and may be mounted in a gear rack along with other networking devices.

The embodiments described herein are unique in that network devices with front facing high-speed I/O connectors are typically configured with a main printed circuit board, oriented in a horizontal plane as is shown in FIG. 1, and connector cages and associated electrical connectors are mounted directly on the horizontal plane of the same main printed circuit board. That is, the connector cages are arranged on the main printed circuit board with front-facing openings of the connector cages at an edge of the main printed circuit board. The main printed circuit board with attached connector cages is then mounted in an enclosure, with the openings of the connector cages arranged at a front side of the enclosure. Thus, to add rows of additional connector cages exposed on the front side of the enclosure, an additional main printed circuit board is stacked inside the enclosure. If multiple printed circuit boards are stacked inside the enclosure in this way to obtain additional rows of connectors, there is less space on the face of the enclosure to allow cooling air to flow into the enclosure, and less space in the enclosure to handle cooling air.

In contrast, the embodiments described herein provide a configuration in which the main processor PCB 110 is separated from the orthogonally-oriented PCB 120 on which the high-speed I/O connectors 510 and associated connector cages 610 are mounted. This hardware configuration opens more space in the enclosure and eliminates air flow blockage caused by multiple main printed circuit boards. That said, the embodiments described herein do not preclude multiple stacked main processor PCBs 110. However, such additional main processor PCBs would have a low profile (since there are no front facing electrical connectors mounted thereon) and providing more space for air circulation in the enclosure.

Referring again to FIG. 4, back-side electrical connectors 410 group multiple respective high-speed electrical I/O signals from/to high-speed I/O connectors 510. In the example depicted, four high-speed I/O connectors 510 are grouped together and managed by a single back-side electrical connector 410 that is connected to main processor PCB 110 via a connection cable 450. Improved cable management is achieved by such aggregation. Also, respective connection cables 450 can be cut/configured to have equal, or substantially equal, lengths, thus reducing any disparate latency that might occur with respect to connection cables 450 of different lengths. Or, the connection cables 450 can have lengths that optimize cable management inside the enclosure.

In accordance with an embodiment, orthogonally-oriented PCB 120 is, effectively, passive. There is no processor mounted on orthogonally-oriented PCB 120 to manage or process high-speed I/O signals to/from high-speed I/O connectors 510. This simplifies the manufacturing process for orthogonally-oriented PCB 120, and permits the number of high-speed I/O connectors 510 to be selected for a given application without concern of “wasting” processing power with a dedicated ASIC. Instead, main processor PCB 110 hosts ASIC 118, which is configured to process high-speed I/O signals to/from high-speed I/O connectors 510. In other words, the PCB that hosts the high-speed I/O connectors 510 is independent of the PCB that hosts ASIC 118, and leverages the processing power of ASIC 118 on main processor PCB 110.

It is noted, however, that orthogonally-oriented PCB 120 may support low-level or low-speed control signaling for control or power considerations. For example, high-speed I/O connectors 510 can be of two variants: passive connectors (e.g., Copper cable), or active connectors (e.g., active cable, optical module). Active connectors rely on additional low-speed control signals such as Inter-Integrated Circuit (I2C) signaling to configure data speed, power settings, other module settings, etc., and power supply. These low-speed signals are normally limited to a few megabytes/second compared to high-speed data signals, which are typically multi gigabits/second signals. In the case of active connectors being used on orthogonally-oriented PCB 120, additional cables (not shown in the figure) may be provided between main processor PCB 110 and orthogonally-oriented PCB 120 for the power supply and low-speed signals.

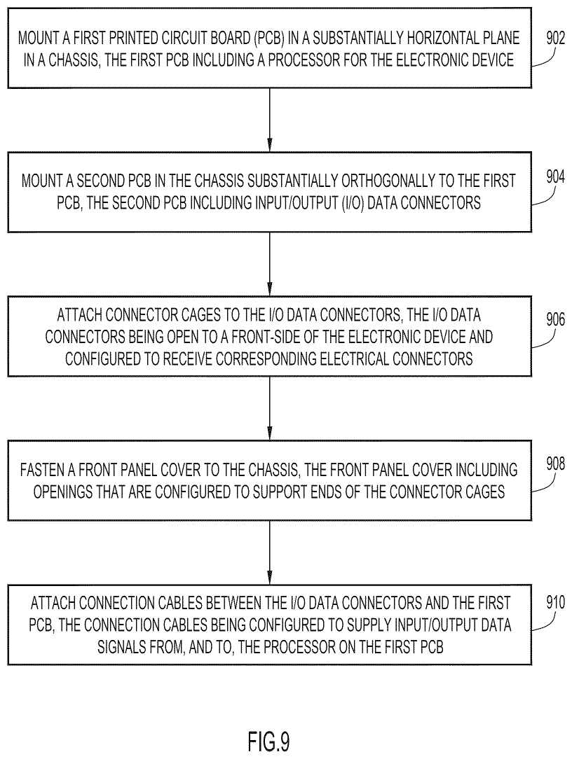

FIG. 9 is a flowchart depicting a series of operations to assemble network device 100, according to an example embodiment. At 902, an operation includes mounting a first printed circuit board (PCB) in a substantially horizontal plane in a chassis, the first PCB including a processor for the electronic device. At 904, an operation includes mounting a second PCB in the chassis substantially orthogonally to the first PCB, the second PCB including high-speed I/O connectors. At 906, an operation includes attaching connector cages to the high-speed I/O connectors, the high-speed connectors being open to a front-side of the electronic device and configured to receive corresponding male electrical connectors. At 908, an operation includes fastening a front panel cover to the chassis, the front panel cover including openings that are configured to support ends of the connector cages. And, at 910, an operation includes attaching connection cables between the high-speed I/O connectors and the first PCB, the connection cables being configured to supply high speed input/output signals from, and to, the processor on the first PCB.

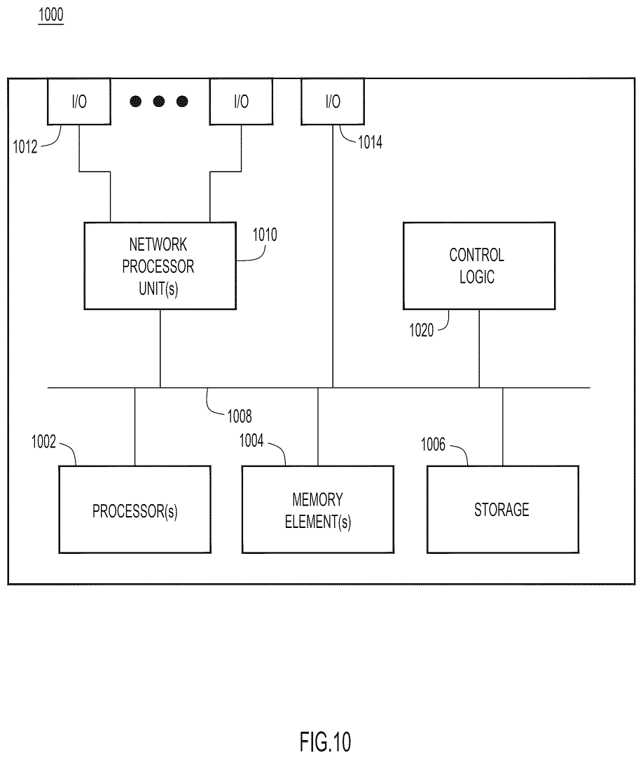

FIG. 10 is a block diagram of a computing device 1000 that may be configured consistent with the described network device 100, according to an example embodiment. In various embodiments, a computing device, such as computing device 1000 or any combination of computing devices 1000, may be configured as any entity/entities as discussed for the techniques depicted in connection with FIGS. 1-9 in order to perform operations of the various techniques discussed herein.

In at least one embodiment, the computing device 1000 may include one or more processor(s) 1002, one or more memory element(s) 1004, storage 1006, a bus 1008, one or more network processor unit(s) 1010 interconnected with one or more network input/output (I/O) interface(s) 1012 (which could make use of the pin-less connector), one or more I/O interface(s) 1014 (which could be configured using the orthogonally-oriented PCB 120), and control logic 1020. In various embodiments, instructions associated with logic for computing device 1000 can overlap in any manner and are not limited to the specific allocation of instructions and/or operations described herein.

In at least one embodiment, processor(s) 1002 is/are at least one hardware processor configured to execute various tasks, operations and/or functions for computing device 1000 as described herein according to software and/or instructions configured for computing device 1000. Processor(s) 1002 (e.g., a hardware processor) can execute any type of instructions associated with data to achieve the operations detailed herein. In one example, processor(s) 1002 can transform an element or an article (e.g., data, information) from one state or thing to another state or thing. Any of potential processing elements, microprocessors, digital signal processor, baseband signal processor, modem, PHY, controllers, systems, managers, logic, and/or machines described herein can be construed as being encompassed within the broad term ‘processor’.

In at least one embodiment, memory element(s) 1004 and/or storage 1006 is/are configured to store data, information, software, and/or instructions associated with computing device 1000, and/or logic configured for memory element(s) 1004 and/or storage 1006. For example, any logic described herein (e.g., control logic 1020) can, in various embodiments, be stored for computing device 1000 using any combination of memory element(s) 1004 and/or storage 1006. Note that in some embodiments, storage 1006 can be consolidated with memory element(s) 1004 (or vice versa) or can overlap/exist in any other suitable manner.

In at least one embodiment, bus 1008 can be configured as an interface that enables one or more elements of computing device 1000 to communicate in order to exchange information and/or data. Bus 1008 can be implemented with any architecture designed for passing control, data and/or information between processors, memory elements/storage, peripheral devices, and/or any other hardware and/or software components that may be configured for computing device 1000. In at least one embodiment, bus 1008 may be implemented as a fast kernel-hosted interconnect, potentially using shared memory between processes (e.g., logic), which can enable efficient communication paths between the processes.

In various embodiments, network processor unit(s) 1010 may enable communication between computing device 1000 and other systems, entities, etc., via network I/O interface(s) 1012 (wired and/or wireless) to facilitate operations discussed for various embodiments described herein. In various embodiments, network processor unit(s) 1010 can be configured as a combination of hardware and/or software, such as one or more Ethernet driver(s) and/or controller(s) or interface cards, Fibre Channel (e.g., optical) driver(s) and/or controller(s), wireless receivers/transmitters/transceivers, baseband processor(s)/modem(s), and/or other similar network interface driver(s) and/or controller(s) now known or hereafter developed to enable communications between computing device 1000 and other systems, entities, etc. to facilitate operations for various embodiments described herein. In various embodiments, network I/O interface(s) 1012 can be configured as one or more Ethernet port(s), Fibre Channel ports, any other I/O port(s), and/or antenna(s)/antenna array(s) now known or hereafter developed. Thus, the network processor unit(s) 1010 and/or network I/O interface(s) 1012 may include suitable interfaces for receiving, transmitting, and/or otherwise communicating data and/or information in a network environment.

I/O interface(s) 1014 allow for input and output of data and/or information with other entities that may be connected to computing device 1000. For example, I/O interface(s) 1014 may provide a connection to external devices such as a keyboard, keypad, a touch screen, and/or any other suitable input and/or output device now known or hereafter developed. In some instances, external devices can also include portable computer readable (non-transitory) storage media such as database systems, thumb drives, portable optical or magnetic disks, and memory cards. In still some instances, external devices can be a mechanism to display data to a user, such as, for example, a computer monitor, a display screen, or the like.

In various embodiments, control logic 1020 can include instructions that, when executed, cause processor(s) 1002 to perform operations, which can include, but not be limited to, providing overall control operations of computing device; interacting with other entities, systems, etc. described herein; maintaining and/or interacting with stored data, information, parameters, etc. (e.g., memory element(s), storage, data structures, databases, tables, etc.); combinations thereof; and/or the like to facilitate various operations for embodiments described herein.

The programs described herein (e.g., control logic 1020) may be identified based upon application(s) for which they are implemented in a specific embodiment. However, it should be appreciated that any particular program nomenclature herein is used merely for convenience; thus, embodiments herein should not be limited to use(s) solely described in any specific application(s) identified and/or implied by such nomenclature.

In various embodiments, entities as described herein may store data/information in any suitable volatile and/or non-volatile memory item (e.g., magnetic hard disk drive, solid state hard drive, semiconductor storage device, random access memory (RAM), read only memory (ROM), erasable programmable read only memory (EPROM), application specific integrated circuit (ASIC), etc.), software, logic (fixed logic, hardware logic, programmable logic, analog logic, digital logic), hardware, and/or in any other suitable component, device, element, and/or object as may be appropriate. Any of the memory items discussed herein should be construed as being encompassed within the broad term ‘memory element’. Data/information being tracked and/or sent to one or more entities as discussed herein could be provided in any database, table, register, list, cache, storage, and/or storage structure: all of which can be referenced at any suitable timeframe. Any such storage options may also be included within the broad term ‘memory element’ as used herein.

Note that in certain example implementations, operations as set forth herein may be implemented by logic encoded in one or more tangible media that is capable of storing instructions and/or digital information and may be inclusive of non-transitory tangible media and/or non-transitory computer readable storage media (e.g., embedded logic provided in: an ASIC, digital signal processing (DSP) instructions, software [potentially inclusive of object code and source code], etc.) for execution by one or more processor(s), and/or other similar machine, etc. Generally, memory element(s) 1004 and/or storage 1006 can store data, software, code, instructions (e.g., processor instructions), logic, parameters, combinations thereof, and/or the like used for operations described herein. This includes memory element(s) 1004 and/or storage 1006 being able to store data, software, code, instructions (e.g., processor instructions), logic, parameters, combinations thereof, or the like that are executed to carry out operations in accordance with teachings of the present disclosure.

In some instances, software of the present embodiments may be available via a non-transitory computer useable medium (e.g., magnetic or optical mediums, magneto-optic mediums, CD-ROM, DVD, memory devices, etc.) of a stationary or portable program product apparatus, downloadable file(s), file wrapper(s), object(s), package(s), container(s), and/or the like. In some instances, non-transitory computer readable storage media may also be removable. For example, a removable hard drive may be used for memory/storage in some implementations. Other examples may include optical and magnetic disks, thumb drives, and smart cards that can be inserted and/or otherwise connected to a computing device for transfer onto another computer readable storage medium.

### Variations and Implementations

Embodiments described herein may include one or more networks, which can represent a series of points and/or network elements of interconnected communication paths for receiving and/or transmitting messages (e.g., packets of information) that propagate through the one or more networks. These network elements offer communicative interfaces that facilitate communications between the network elements. A network can include any number of hardware and/or software elements coupled to (and in communication with) each other through a communication medium. Such networks can include, but are not limited to, any local area network (LAN), virtual LAN (VLAN), wide area network (WAN) (e.g., the Internet), software defined WAN (SD-WAN), wireless local area (WLA) access network, wireless wide area (WWA) access network, metropolitan area network (MAN), Intranet, Extranet, virtual private network (VPN), Low Power Network (LPN), Low Power Wide Area Network (LPWAN), Machine to Machine (M2M) network, Internet of Things (IoT) network, Ethernet network/switching system, any other appropriate architecture and/or system that facilitates communications in a network environment, and/or any suitable combination thereof.

Networks through which communications propagate can use any suitable technologies for communications including wireless communications (e.g., 4G/5G/nG, IEEE 802.11 (e.g., Wi-Fi®/Wi-Fi 6®), IEEE 802.16 (e.g., Worldwide Interoperability for Microwave Access (WiMAX)), Radio-Frequency Identification (RFID), Near Field Communication (NFC), Bluetooth™, mm. wave, Ultra-Wideband (UWB), etc.), and/or wired communications (e.g., T1 lines, T3 lines, digital subscriber lines (DSL), Ethernet, Fibre Channel, etc.). Generally, any suitable means of communications may be used such as electric, sound, light, infrared, and/or radio to facilitate communications through one or more networks in accordance with embodiments herein. Communications, interactions, operations, etc. as discussed for various embodiments described herein may be performed among entities that may directly or indirectly connected utilizing any algorithms, communication protocols, interfaces, etc. (proprietary and/or non-proprietary) that allow for the exchange of data and/or information.

Communications in a network environment can be referred to herein as ‘messages’, ‘messaging’, ‘signaling’, ‘data’, ‘content’, ‘objects’, ‘requests’, ‘queries’, ‘responses’, ‘replies’, etc. which may be inclusive of packets. As referred to herein and in the claims, the term ‘packet’ may be used in a generic sense to include packets, frames, segments, datagrams, and/or any other generic units that may be used to transmit communications in a network environment. Generally, a packet is a formatted unit of data that can contain control or routing information (e.g., source and destination address, source and destination port, etc.) and data, which is also sometimes referred to as a ‘payload’, ‘data payload’, and variations thereof. In some embodiments, control or routing information, management information, or the like can be included in packet fields, such as within header(s) and/or trailer(s) of packets. Internet Protocol (IP) addresses discussed herein and in the claims can include any IP version 4 (IPv4) and/or IP version 6 (IPv6) addresses.

To the extent that embodiments presented herein relate to the storage of data, the embodiments may employ any number of any conventional or other databases, data stores or storage structures (e.g., files, databases, data structures, data or other repositories, etc.) to store information.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’nomenclature (e.g., one or more element(s)).

In sum, an electronic device has been described and includes a chassis, a first printed circuit board (PCB) mounted in a substantially horizontal plane in the chassis, the first PCB including a processor for the electronic device, a second PCB mounted in the chassis substantially orthogonally to the first PCB, the second PCB including first electrical connector components that are exposed to a front-side of the electronic device and are respectively configured to receive corresponding second electrical connector components, and connection cables, connecting the first electrical connector components to the first PCB, the connection cables configured to supply input/output data signals from, and to, the processor on the first PCB.

In the electronic device, the second PCB may be configured to supply power and control signals to the first electrical connector components.

In the electronic device, the second PCB comprises air flow passages.

In the electronic device, the air flow passages comprise first air flow passages having a first area, and second air flow passages having a second area smaller than the first area.

In the electronic device, the air flow passages may extend horizontally under respective groups of the first electrical connector components.

In the electronic device, the connection cables may be substantially equal in length.

In the electronic device, the connection cables may aggregate the input/output data signals of respective groups of the first electrical connector components.

The electronic device may be at least one of a switch and a router.

The electronic device may further include back-side connectors that connect the connection cables to a back side of the second PCB.

In the electronic device, the first electrical connector components are one of Quad Small Form-factor Pluggable (QSFP), QSFP Double Density (QSFP-DD), or Octal Small Form-Factor Pluggable (OSFP) type connector components.

In another embodiment, an electronic device includes a chassis, a first printed circuit board (PCB) mounted in a substantially horizontal plane in the chassis, the first PCB including a processor for the electronic device, a second PCB mounted in the chassis substantially orthogonally to the first PCB, the second PCB including input/output data connectors, connector cages respectively attached to the input/output data connectors and open to a front-side of the electronic device, the connector cages configured to receive corresponding male electrical connectors, a front panel cover including openings configured to support ends of the connector cages, and connection cables, connecting the input/output data connectors to the first PCB, and configured to supply input/output data signals from, and to, the processor on the first PCB.

In the electronic device, the second PCB may be configured to supply power and control signals to the input/output data connectors.

In the electronic device, the second PCB may include air flow passages.

In the electronic device, the air flow passages may include first air flow passages having a first area, and second air flow passages having a second area smaller than the first area.

In the electronic device, the connection cables may be substantially equal in length.

In the electronic device, the connection cables may aggregate the input/output data signals of respective groups of the input/output data connectors.

The electronic device may be at least one of a switch and a router.

A method for assembling an electronic device is also described. The method includes mounting a first printed circuit board (PCB) in a substantially horizontal plane in a chassis, the first PCB including a processor for the electronic device, mounting a second PCB in the chassis substantially orthogonally to the first PCB, the second PCB including input/output data connectors, attaching connector cages to the input/output data connectors, the input/output data connectors being open to a front-side of the electronic device and configured to receive corresponding electrical connectors, fastening a front panel cover to the chassis, the front panel cover including openings that are configured to support ends of the connector cages, and attaching connection cables between the input/output data connectors and the first PCB, the connection cables being configured to supply input/output data signals from, and to, the processor on the first PCB.

In the method, the connector cages may be configured to receive one of Quad Small Form-factor Pluggable (QSFP), QSFP Double Density (QSFP-DD), or Octal Small Form-Factor Pluggable (OSFP) type connector components.

The method may further include supplying power and control signals to the input/output data connectors.

Each example embodiment disclosed herein has been included to present one or more different features. However, all disclosed example embodiments are designed to work together as part of a single larger system or method. This disclosure explicitly envisions compound embodiments that combine multiple previously discussed features in different example embodiments into a single system or method.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. An electronic device comprising:
a chassis;
a first printed circuit board (PCB) mounted in a substantially horizontal plane in the chassis, the first PCB including a processor for the electronic device;
a second PCB mounted in the chassis substantially orthogonally to the first PCB, the second PCB including first electrical connector components that are exposed to a front-side of the electronic device and are respectively configured to receive corresponding second electrical connector components; and
connection cables, connecting the first electrical connector components to the first PCB, the connection cables configured to supply input/output data signals from, and to, the processor on the first PCB.

2. The electronic device of claim 1, wherein the second PCB is configured to supply power and control signals to the first electrical connector components.

3. The electronic device of claim 1, wherein the second PCB comprises air flow passages.

4. The electronic device of claim 3, wherein the air flow passages comprise first air flow passages having a first area, and second air flow passages having a second area smaller than the first area.

5. The electronic device of claim 3, wherein the air flow passages extend horizontally under respective groups of the first electrical connector components.

6. The electronic device of claim 1, wherein the connection cables are substantially equal in length.

7. The electronic device of claim 1, wherein the connection cables aggregate the input/output data signals of respective groups of the first electrical connector components.

8. The electronic device of claim 1, wherein the electronic device is at least one of a switch and a router.

9. The electronic device of claim 1, further comprising back-side connectors that connect the connection cables to a back side of the second PCB.

10. The electronic device of claim 1, wherein the first electrical connector components are one of Quad Small Form-factor Pluggable (QSFP), QSFP Double Density (QSFP-DD), or Octal Small Form-Factor Pluggable (OSFP) type connector components.

11. An electronic device comprising:
a chassis;
a first printed circuit board (PCB) mounted in a substantially horizontal plane in the chassis, the first PCB including a processor for the electronic device;
a second PCB mounted in the chassis substantially orthogonally to the first PCB, the second PCB including input/output data connectors;
connector cages respectively attached to the input/output data connectors and open to a front-side of the electronic device, the connector cages configured to receive corresponding male electrical connectors;
a front panel cover including openings configured to support ends of the connector cages; and
connection cables, connecting the input/output data connectors to the first PCB, and configured to supply input/output data signals from, and to, the processor on the first PCB.

12. The electronic device of claim 11, wherein the second PCB is configured to supply power and control signals to the input/output data connectors.

13. The electronic device of claim 11, wherein the second PCB comprises air flow passages.

14. The electronic device of claim 13, wherein the air flow passages comprise first air flow passages having a first area, and second air flow passages having a second area smaller than the first area.

15. The electronic device of claim 11, wherein the connection cables are substantially equal in length.

16. The electronic device of claim 11, wherein the connection cables aggregate the input/output data signals of respective groups of the input/output data connectors.

17. The electronic device of claim 11, wherein the electronic device is at least one of a switch and a router.

18. A method for assembling an electronic device, comprising:
mounting a first printed circuit board (PCB) in a substantially horizontal plane in a chassis, the first PCB including a processor for the electronic device;
mounting a second PCB in the chassis substantially orthogonally to the first PCB, the second PCB including input/output data connectors;
attaching connector cages to the input/output data connectors, the input/output data connectors being open to a front-side of the electronic device and configured to receive corresponding electrical connectors;
fastening a front panel cover to the chassis, the front panel cover including openings that are configured to support ends of the connector cages; and
attaching connection cables between the input/output data connectors and the first PCB, the connection cables being configured to supply input/output data signals from, and to, the processor on the first PCB.

19. The method of claim 18, wherein the connector cages configured to receive one of Quad Small Form-factor Pluggable (QSFP), QSFP Double Density (QSFP-DD), or Octal Small Form-Factor Pluggable (OSFP) type connector components.

20. The method of claim 18, further comprising supplying power and control signals to the input/output data connectors.
